(19) United States
(12) Patent Application Publication
(10) Pub. No.: US 2013/0163158 A1
(43) Pub. Date: Jun. 27, 2013

(54) TERMINAL APPARATUS

(71) Applicant: Sony Mobile Communications Japan, Inc., Minato-ku (JP)

(72) Inventor: Tatsuya SANO, Tokyo (JP)

(73) Assignee: Sony Mobile Communications Japan, Inc., Minato-ku (JP)

(21) Appl. No.: 13/681,167

(22) Filed: Nov. 19, 2012

Related U.S. Application Data
(60) Provisional application No. 61/566,346, filed on Dec. 2, 2011.

(51) Int. Cl. H05K 5/02

(52) U.S. Cl. CPC H05K 5/0226
USPC 361/679.01

(57) ABSTRACT

A terminal apparatus including a first housing; a second housing; and a slide hinge that couples the second housing to the first housing such that the second housing is slidable with respect to the first housing in a first direction between a closed state and an open state. The slide hinge includes a support plate fixed to the second housing, a movable plate slidably coupled to the first housing with respect to the support plate along the first direction, an intermediate plate slidably supported by the support plate with respect to the support plate in the second direction, and a cam mechanism that slides the intermediate plate in the second direction in accordance with a slide operation of the movable plate along the first direction.

### CROSS REFERENCE TO RELATED APPLICATIONS

This application is related to and claims priority under 35 U.S.C. §119(e) to Provisional Application Ser. No. 61/566,346, filed Dec. 2, 2012, the contents of which are hereby incorporated herein by reference.

### BACKGROUND

1. Field

The present specification relates to a portable terminal which includes a first housing serving as a lower housing and a second housing serving as an upper housing and in which the second housing performs a slide operation with respect to the first housing, and to a slide hinge for the portable terminal.

2. Description of the Related Art

Recently, portable terminals represented by cellular phone terminals have been widely used, and improvements in portability, display viewability, and convenience of the portable terminals have been sought after. A slide type in which an upper housing is coupled to a lower housing by a slide hinge so as to be slidable with respect to the lower housing is known as a type of the portable terminals. In the closed state, the upper housing serving is placed over a surface of the lower housing with a display screen of the upper housing facing upward. In the open state, the upper housing is slid with respect to the lower housing in parallel with the lower housing to expose most of the surface of the lower housing which has been hidden behind the upper housing. Typically, an operating section such as a keyboard is disposed on the surface of the lower housing.

In order to achieve the slide operation of such slide-type portable terminals, a slide hinge module in which the elastic force of an elastic spring is used to assist a user in performing the slide operation of the housings has hitherto been proposed (see Patent Document 1). The slide hinge module is intended for a type of cellular phone terminals in which an upper housing, in which a display section is disposed, is slid with respect to a lower housing, in which a keyboard is disposed, to be opened and closed.

The slide hinge module which couples between the lower housing and the upper housing is formed by a fixed plate and a moving plate slidably coupled to the fixed plate, with an elastic spring mounted between the two plates. The elastic spring provides an elastic force that semi-automatically slides the moving plate with respect to the fixed plate. More specifically, the moving plate is slid by an external force provided by the user, against the elastic force of the elastic spring, from one end of the moving range to the dead point at the middle of the moving range. After the moving plate is moved beyond the dead point by a subsequent continuous operation, the moving plate is automatically moved by the elastic force of the elastic spring in the direction of the opposite end portion across the dead point. In the case where the external force is removed before the moving plate reaches the dead point, the moving plate is automatically moved by the elastic force of the elastic spring back to the end portion where the moving plate originally was. This causes the portable terminal to transition into a stable state, that is, either of the open state and the closed state.

### CITATION LIST

### Patent Literature

[PTL 1] Japanese Unexamined Patent Application Publication No. 2010-279015

For the slide-type portable terminals discussed above, it is requested not only to reduce the size of the entire set, but also to increase the area of the lower housing to be exposed in the open state. This request is based on a desire for an improvement in usability of the operating section such as a keyboard disposed in the lower housing.

In order to increase the area of the lower housing to be exposed in the open state in the existing slide-type portable terminals, it is necessary to reduce the amount of overlap between the upper and lower housings.

If it is attempted to reduce the amount of overlap between the upper and lower housings, however, the slide hinge structure according to the related art may rattle the upper housing with respect to the lower housing in the rotational direction about an axis perpendicular to the upper housing, that is, increase so-called angular backlash.

Against such background, the inventor recognizes the need to suppress an increase in angular backlash between first and second housings of a portable terminal coupled to each other by a slide hinge while reducing the amount of overlap between the two housings.

### BRIEF SUMMARY

According to an embodiment, there is provided a terminal apparatus including: a first housing; a second housing; and a slide hinge that couples the second housing to the first housing such that the second housing is slidable with respect to the first housing in a first direction between a closed state and an open state. The slide hinge includes a support plate fixed to the second housing, a movable plate slidably coupled to the first housing with respect to the support plate along the first direction, an intermediate plate slidably supported by the support plate with respect to the support plate in the second direction, and a cam mechanism that slides the intermediate plate in the second direction in accordance with a slide operation of the movable plate along the first direction.

According to the embodiment, the slide hinge is provided with the intermediate plate, and the cam mechanism associated with the intermediate plate. Thus, angular backlash between the first and second housings can be effectively suppressed.

The portable terminal may further include an elastic member that exerts an urging force in the direction of moving the intermediate plate away from or closer to the support plate along the second direction such that the portable terminal is brought into first and second stable states with the movable plate at one end and the other end, respectively, of a moving range in the first direction.

In another embodiment, the slide hinge may include a notched portion provided in a back surface to allow passage of a flexible cable for electrical connection between the first housing and the second housing. In this case, the slide hinge may further include a shutter member that blocks a portion of the notched portion that is exposed in the open state, and the shutter member and the intermediate plate may include a second cam mechanism. The second cam mechanism may cause the shutter member to open and close the notched portion in conjunction with movement of the intermediate plate.

According to an embodiment, there is additionally provided a slide hinge that couples a second housing to a first housing so as to be slidable with respect to the first housing in a first direction between a closed state and an open state. The slide hinge includes: a support plate fixed to the second housing; a movable plate coupled to the first housing and supported so as to be slidable with respect to the support plate along the first direction; and an intermediate plate that cooperates with the support plate and the movable plate. The intermediate plate is supported by the support plate so as to be slidable with respect to the support plate in a second direction. The intermediate plate and the movable plate may include a cam mechanism that slides the intermediate plate in the second direction in accordance with a slide operation of the movable plate along the first direction.

### BRIEF DESCRIPTION OF THE DRAWINGS

FIGS. 1(a) and 1(b) show a schematic appearance of a portable terminal according to an embodiment.

FIG. 2 is an exploded view showing the structure in which a slide hinge that achieves a slide operation as shown in FIG. 1 is interposed between a first housing and a second housing.

FIG. 3 is an exploded perspective view showing a specific example of the structure of the slide hinge shown in FIG. 2.

FIG. 4 is an enlarged view showing a schematic configuration of an essential portion of the slide hinge shown in FIG. 3 as seen from a side surface.

FIGS. 5(a), 5(b), 5(c), 5(d), 5(e) and 5(f) illustrate an operation of the slide hinge shown in FIG. 3.

FIGS. 6(a) and 6(b) illustrate the structure of a slide hinge having no intermediate plate, and the difference in effect between the slide hinge having no intermediate plate and a slide hinge having an intermediate plate.

FIGS. 7(a) and 7(b) illustrate an issue to be addressed by a second embodiment.

FIGS. 8(a) and 8(b) illustrate a shutter mechanism that opens and closes a shutter member according to the second embodiment.

FIG. 9 is an exploded perspective view showing a specific example of the structure of a slide hinge according to the second embodiment.

FIGS. 10(a) and 10(b) are each a schematic diagram showing how a flexible cable passes through a slide hinge in a portable terminal according to the second embodiment.

FIGS. 11(a), 11(b), and 11(c) illustrate an operation of the slide hinge according to the second embodiment.

FIGS. 12(a), 12(b), and 12(c) show the slide hinge in a closed state, an intermediate state, and an open state, respectively, as seen from a back surface.

FIG. 13 is a side view of a main portion of the slide hinge in the state of FIG. 11(b) as seen from the front side.

FIG. 14 is an exploded perspective view of a slide hinge according to a modification of the second embodiment.

FIGS. 15(a), 15(b), and 15(c) illustrate an operation of the slide hinge according to the modification of FIG. 14.

FIGS. 16(a) and 16b illustrate the effect of the first and second embodiments.

FIG. 17 is an exploded perspective view of a slide hinge according to another modification of the second embodiment.

FIGS. 18(a), 18(b), 18(c) illustrate an operation of the slide hinge according to the modification of FIG. 17.

### DETAILED DESCRIPTION

Embodiments will be described in detail below with reference to the drawings.

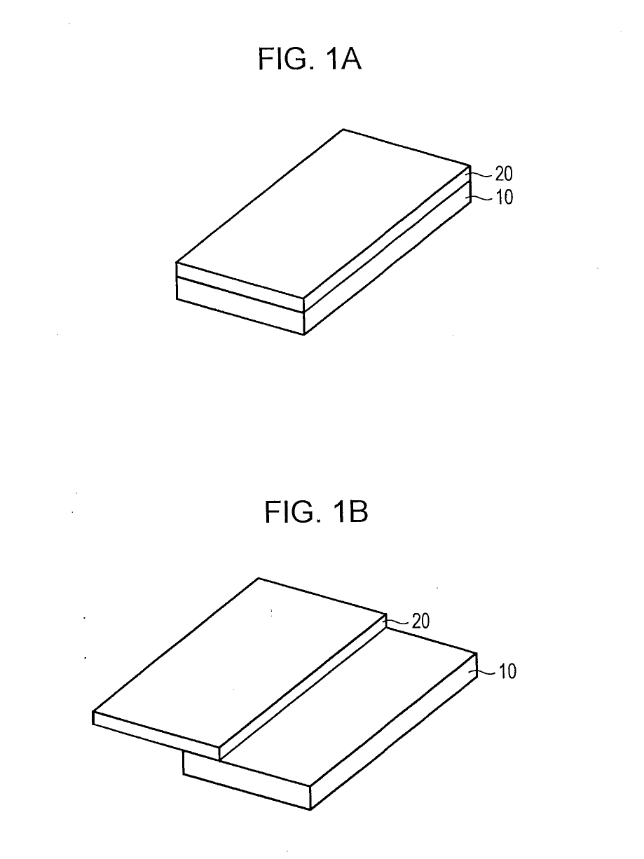

FIG. 1 shows a schematic appearance of a portable terminal according to an embodiment. FIG. 1(a) is a perspective view showing the portable terminal in the closed state. FIG. 1(b) is a perspective view showing the portable terminal in the open state. The portable terminal includes a first housing 10 serving as a lower housing and a second housing 20 serving as an upper housing.

When the portable terminal is in the closed state (that is, in the closed attitude), the second housing 20 is placed over the first housing 10 with the display screen of the second housing 20 facing upward. When the portable terminal is in the open state (that is, in the open attitude), the second housing 20 has been slid with respect to the first housing 10 in parallel with the first housing 10. In this state, most of the surface of the first housing 10 is exposed to the outside. An operating section such as a keyboard is disposed on the surface of the first housing 10. In place of the operating section, a second display device may be disposed with its display screen facing upward. A touch screen in which a touch area is placed on a display screen may be used as the display device.

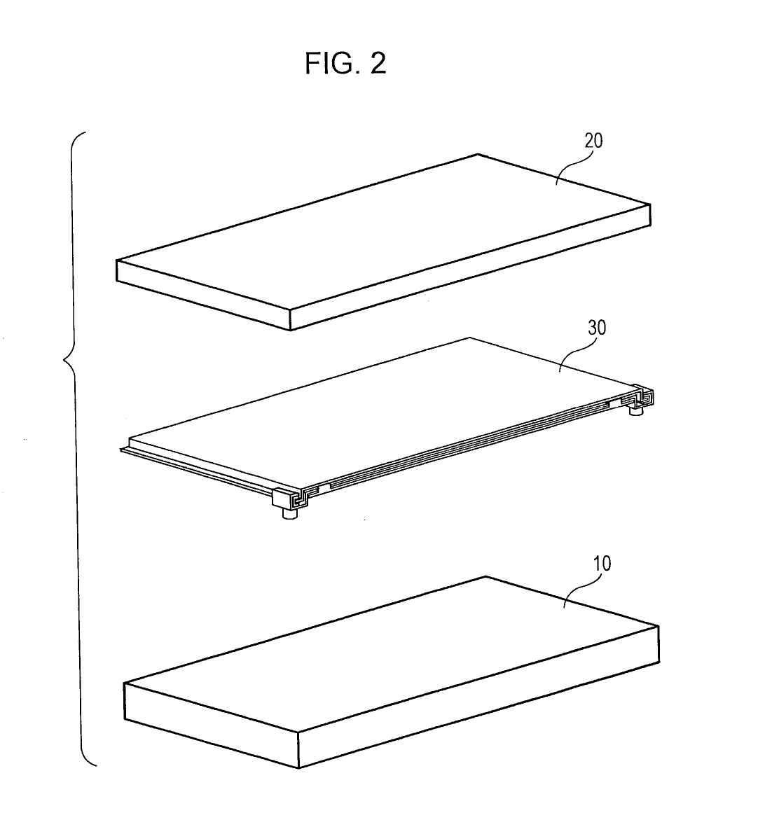

FIG. 2 is an exploded view showing the structure in which a slide hinge (or a slide mechanism) 30 is interposed between the first housing 10 and the second housing 20 as specific means for achieving a slide operation as shown in FIG. 1.

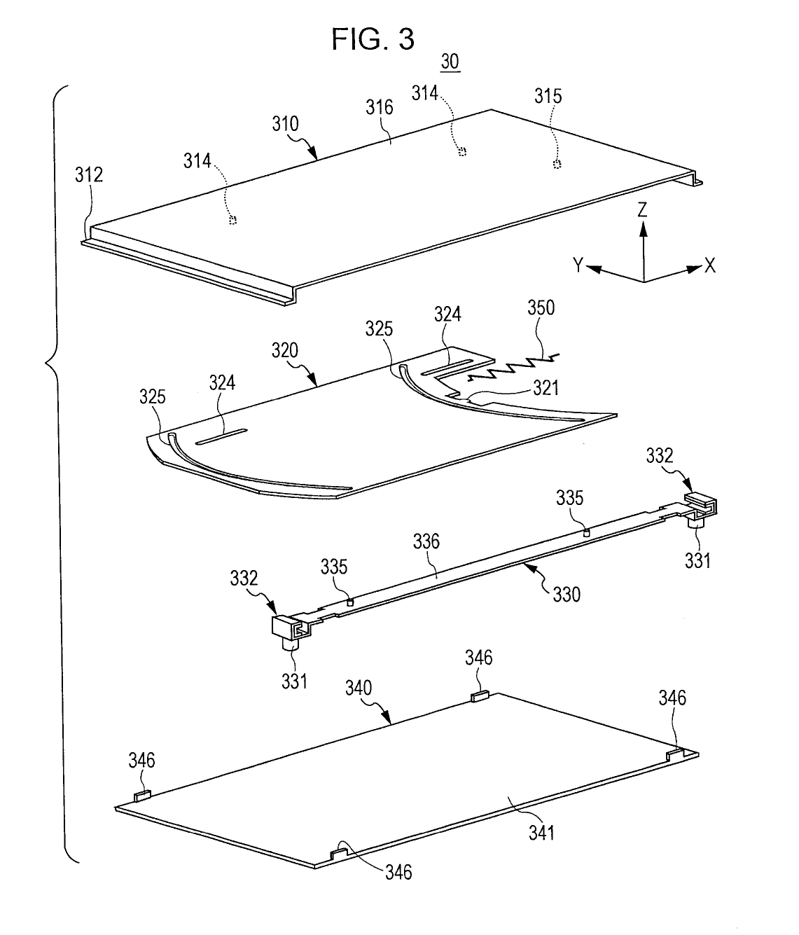

FIG. 3 is an exploded perspective view showing a specific example of the structure of the slide hinge 30.

The slide hinge 30 is a hinge that couples the second housing 20 to the first housing 10 so as to be slidable with respect to the first housing 10 in a first direction (Y-axis direction) between the closed state and the open state of the portable terminal. The slide hinge 30 is formed by a support plate 310, an intermediate plate 320, a movable plate 330, a back surface cover 340, and a spring 350. The material of each element of the slide hinge 30 is not specifically limited, and may be a material such as plastic, metal, and alloy, for example. For the purpose of description, the longitudinal direction of the movable plate 330 (that is, the direction along the long sides of the support plate 310) is defined as the X axis, and the direction along the short sides of the support plate 310 is defined as the Y axis. In addition, the direction perpendicular to both the X axis and the Y axis is defined as the Z axis.

The support plate 310 fixedly supports the second housing 20 on top thereof, and supports the movable plate 330 thereunder so as to be slidable through guide rail portions 312 formed at lateral side portions (here, along short sides) of the support plate 310 and opposing each other. The guide rail portions 312 are formed by bending the lateral side portions of a flat plate member 316 once to a substantially right angle and then bending the lateral side portions once in the opposite direction. However, the configuration of the guide rail portions 312 is not limited thereto. The means for fixing the support plate 310 to the second housing 20 is not specifically limited. For example, the support plate 310 may be fixed by screwing or the like.

The movable plate 330 is fixedly coupled to the first housing 10, and supported so as to be slidable with respect to the support plate 310 along the first direction. In the example, the movable plate 330 is formed by a plate-like member 336 formed in a belt shape. The movable plate 330 includes slide engagement portions 332 provided at both end portions of the movable plate 330 to slidably engage with the guide rail portions 312 of the support plate 310. In the example, the slide engagement portions 332 are formed by bending the end portions of the plate-like member 336 three times in the same direction and then bending the end portions once in the opposite direction. Attachment portions 331 for attachment to the first housing 10 are provided under both ends (in the example, the slide engagement portions 332) of the movable plate 330. The movable plate 330 is fixed to the first housing 10 via the attachment portions 331. The means for fixation is not specifically limited. For example, the movable plate 330 may be fixed by screwing or the like.

The intermediate plate 320 is disposed between the support plate 310 and the movable plate 330 to cooperate with the support plate 310 and the movable plate 330. That is, the intermediate plate 320 and the movable plate 330 include a cam mechanism. The cam mechanism converts a slide operation (reciprocal operation) of the movable plate 330 (driver) along the first direction into a predetermined slide operation of the intermediate plate 320 (follower) along the second direction. Consequently, as the movable plate 330 relatively moves with respect to the support plate 310 in the Y-axis direction (first direction), the intermediate plate 320 moves in the X-axis direction (second direction) which is substantially orthogonal to the Y-axis direction.

The cam mechanism is formed by first and second cam grooves 325 provided in the intermediate plate 320, and first and second projecting portions 335 provided on the movable plate 330 to engage with the first and second cam grooves 325, respectively. The first and second projecting portions 335 are provided on a surface of the movable plate 330 at positions apart from each other in the longitudinal direction of the movable plate 330 to extend straight upward (in the positive Z-axis direction). In the embodiment, the projecting portions 335 are formed by pins.

In addition, the intermediate plate 320 and the support plate 310 include a guide mechanism that guides the intermediate plate 320 as the intermediate plate 320 slides along the X-axis direction. The guide mechanism is formed by first and second guide grooves 324 provided in the intermediate plate 320 to extend straight, and first and second projecting portions (engagement shafts) 314 provided on the back surface of the support plate 310 to extend upright. The first and second projecting portions 314 slidably engage with the corresponding guide grooves 324. In the embodiment, the first guide groove 324 and the second guide groove 324 are positioned apart from each other on the X axis. The first guide groove 324 and the second guide groove 324 are positioned at the same position as each other on the Y axis. Alternatively, the first and second guide grooves 324 may be positioned at different positions from each other on the Y axis. Similarly, the first projecting portion 314 and the second projecting portion 314 are positioned apart from each other on the X axis. The first projecting portion 314 and the second projecting portion 314 are positioned at the same position as each other on the Y axis, but may be positioned at different positions from each other on the Y axis.

Further, in order to establish first and second stable states with the movable plate 330 at one end and the other end, respectively, of a moving range (movable range) in the Y-axis direction, the slide hinge 30 includes an elastic member that exerts an urging force to the intermediate plate 320 with reference to the support plate 310. Here, the elastic member is formed by a spring 350. The spring 350 is a compression spring that, when compressed, generates a repulsive force with a magnitude corresponding to the amount of compression. The spring 350 exerts an urging force in the direction of moving the intermediate plate 320 away from the support plate 310 along the X-axis direction. One end of the spring 350 is fixed to a predetermined position of the support plate 310, that is, a fastening portion 315 provided substantially at the middle on the side of one end of the back surface of the support plate 310. The other end of the spring 350 is fixed to a fastening portion 321 provided substantially at the middle on the side of one end of the intermediate plate 320.

The illustrated spring 350 merely schematically shows its function, and does not indicate its actual shape or structure. The spring 350 may be a tension spring that exerts an urging force in the direction of moving the intermediate plate 320 closer to the support plate 310 along the X-axis direction. In this case, the direction of convexity of the arcuate first and second cam grooves 325 is inverted. In addition, more than one spring may be used. The position and arrangement of the spring is also not limited to those shown.

The back surface cover 340 is formed by a flat plate member 341, and disposed to cover the intermediate plate 320 and the movable plate 330 from behind to be coupled to the support plate 310. The specific method of coupling is not limited. The back surface cover 340 is formed by the flat plate member 341, and lugs 346 are provided in the vicinity of the four corners of the flat plate member 341 to extend straight upward (in the positive Z-axis direction) from lateral sides of the flat plate member 341. In the example, the lugs 346 define the dimension of a gap formed between the support plate 310 and the back surface cover 340.

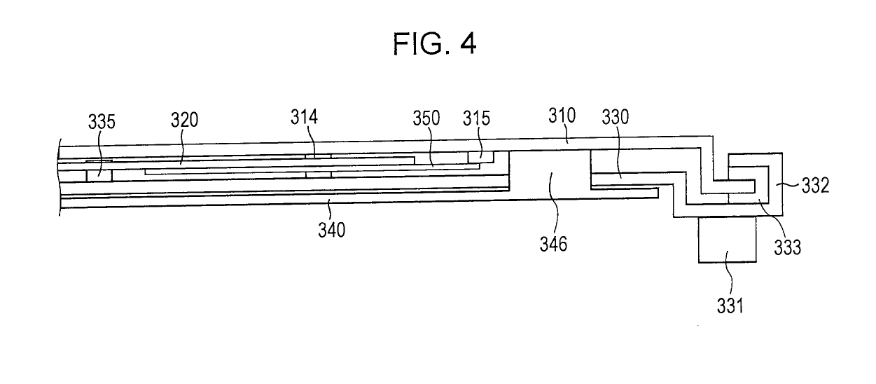

FIG. 4 is an enlarged view showing a schematic configuration of an essential portion of the slide hinge 30 as seen from a side surface. As seen from the drawing, the height of the lugs 346 is determined as follows. That is, the height of the lugs 346 is set so as to ensure that movement of the movable plate 330 in the Y-axis direction and movement of the intermediate plate 320 in the X-axis direction will not be obstructed in a space formed between the support plate 310 and the back surface cover 340. The method of coupling between the back surface cover 340 and the support plate 310 is not specifically limited.

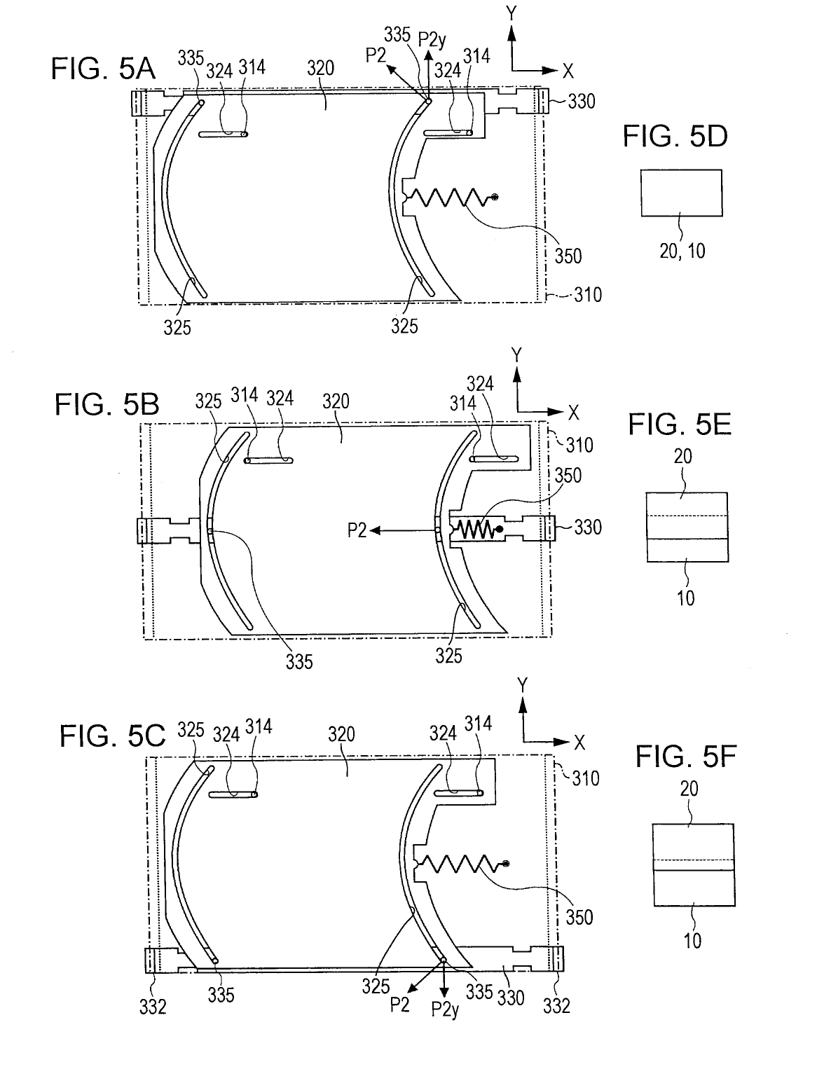

Next, an operation of the slide hinge 30 will be described with reference to FIG. 5. FIGS. 5(a) to 5(c) show the state of the slide hinge 30 with the portable terminal in the closed state, the intermediate state (half-open state), and the open state, respectively. In the drawings, the portable terminal is seen from the upper surface side. For convenience, the support plate 310 is removed, and indicated by the phantom line. FIGS. 5(d) to 5(f) schematically show the portable terminal in the closed state, the intermediate state, and the open state, respectively, corresponding to FIGS. 5(a) to 5(c).

For convenience, the closed state of FIGS. 5(a) and 5(d) is described first. When the portable terminal is in the closed state as shown in FIG. 5(d), the second housing 20 is placed over the first housing 10. At this time, the slide hinge 30 is in the state shown in FIG. 5(a). That is, the projecting portion 335 of the movable plate 330 receives a force represented by a vector P2 from a wall surface of the cam groove 325 of the intermediate plate 320. At this time, the tangent to the arc of the arcuate cam groove 325 at the point at which the projecting portion 335 is positioned is inclined from the direction (that is, the Y-axis direction) perpendicular to the longitudinal direction of the movable plate 330. Thus, a force in the direction of the vector P2 includes a Y-axis component P2y. Consequently, the movable plate 330 receives a force in the positive Y-axis direction (upward in the drawing) with reference to the support plate 310. As a result, the second housing 20 coupled to the support plate 310 is maintained in the closed state with respect to the first housing 10 coupled to the movable plate 330. This state corresponds to the first stable state of the portable terminal.

When a user slides the second housing 20 upward with respect to the first housing 10 from the closed state of FIG. 5(d), the movable plate 330 is relatively moved with respect to the support plate 310 to transition from the state of FIG. 5(a) to the state of FIG. 5(b). If it is assumed that the first housing 10 is stationary, it can be considered that the support plate 310 has been moved with respect to the movable plate 330 which is stationary. The projecting portions 335 on the movable plate 330 slidably engage with the cam grooves 325 in the intermediate plate 320. Because movement of the movable plate 330 in the X-axis direction is restricted, movement of the projecting portions 335 in the lateral direction is also restricted. In addition, the cam grooves 325 are curved to be convex in the negative X-axis direction.

Thus, as the movable plate 330 moves downward (in the negative Y-axis direction) with respect to the support plate 310 from the state of FIG. 5(a), the intermediate plate 320 moves rightward while compressing the spring 350. At this point, the tangent to the arc of the cam groove 325 at the point at which the projecting portion 335 is positioned perfectly coincides with the Y-axis direction of the movable plate 330.

Thus, the Y-axis component P2y in this state is 0. This means that the movable plate 330 is positioned at the dead point with respect to the support plate 310. At the dead point, the portable terminal is in an unstable state, in which the portable terminal is urged to transition into either the open state and the closed state.

If the movable plate 330 is moved downward, even only slightly, from the state of FIG. 5(b) by a continuous operation performed by the user, the sign of the Y-axis component P2y is inverted. As a result, the movable plate 330 is urged in the direction of moving downward with respect to the support plate 310. This means that the second housing 20 has started moving in the positive Y-axis direction with respect to the first housing 10. Thereafter, the movable plate 330 is moved by the spring force to the lowermost end of the support plate 310 as shown in FIG. 5(c). That is, the second housing 20 moves with respect to the first housing 10 to transition from the state of FIG. 5(e) to the open state of FIG. 5(f). This state corresponds to the second stable state of the portable terminal.

Transition of the portable terminal from the open state into the closed state follows the steps discussed above in the reverse order.

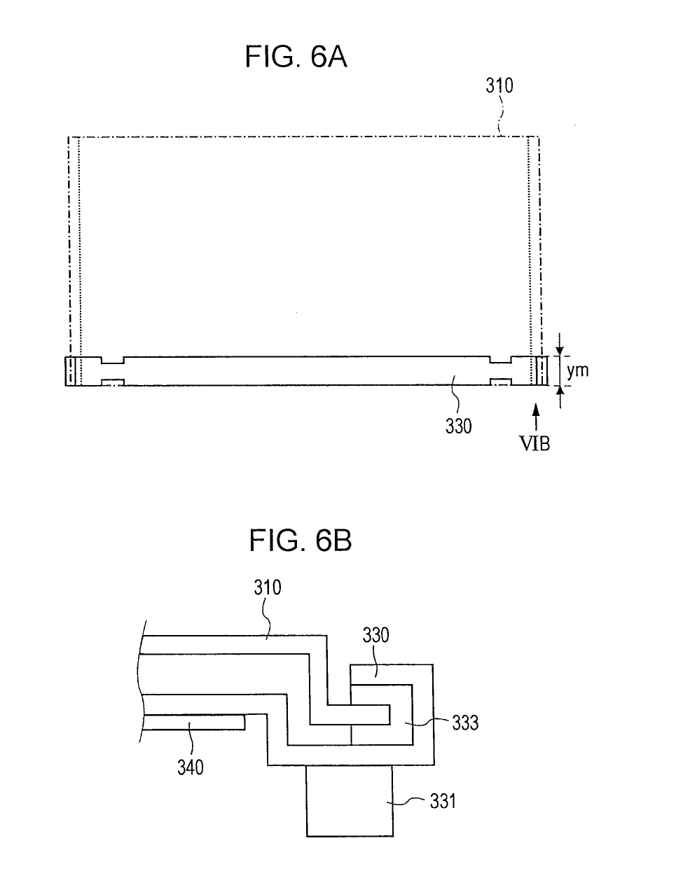

Here, FIG. 6 shows the structure of a slide hinge having no intermediate plate 320, and illustrates the difference in effect between the slide hinge having no intermediate plate 320 and a slide hinge having the intermediate plate 320. FIG. 6(a) is a plan view of the slide hinge having no intermediate plate 320. The uppermost support plate 310 is indicated by the phantom line (dot-and-dash line). FIG. 6(b) is an enlarged side view of an essential portion of the slide hinge as seen from the direction of the arrow in FIG. 6(a).

In order to reduce the amount of overlap between the first housing 10 and the second housing 20 in the open state as discussed above, it is necessary to reduce the width ym of the movable plate 330. For a slide hinge having no intermediate plate 320 as shown in FIG. 6(a), however, rotational backlash of the movable plate 330 with respect to the support plate 310 about an axis perpendicular to the support plate 310 becomes larger as the width ym of the movable plate 330 becomes smaller. Such rotational backlash also depends on the dimension of the gap between both end portions of the support plate 310 and the slide engagement portions 332 of the movable plate 330 in which the end portions of the support plate 310 are fitted. In order to maintain a favorable slide operation of the movable plate 330 with respect to the support plate 310, however, it is necessary to avoid excessive friction between the two plates. Thus, there is a limit to narrowing the gap between the two plates. Even if the gap were narrowed to the limit, larger rotational backlash would inevitably be caused as the width ym of the movable plate 330 is smaller.

In contrast, as shown in FIG. 5, the constituent elements of the slide hinge 30 according to the embodiment include the intermediate plate 320 in addition to the support plate 310 and the movable plate 330. The cam mechanism discussed above is provided in association with the intermediate plate 320 and the movable plate 330, and the guide mechanism discussed above is provided in association with the intermediate plate 320 and the support plate 310. The guide mechanism guides the intermediate plate 320 such that the intermediate plate 320 slides with respect to the support plate 310 in a predetermined direction (in the example, in the X-axis direction) in cooperation with the cam mechanism. In addition, the guide mechanism functions to minimize rotational backlash of the movable plate 330 with respect to the support plate 310.

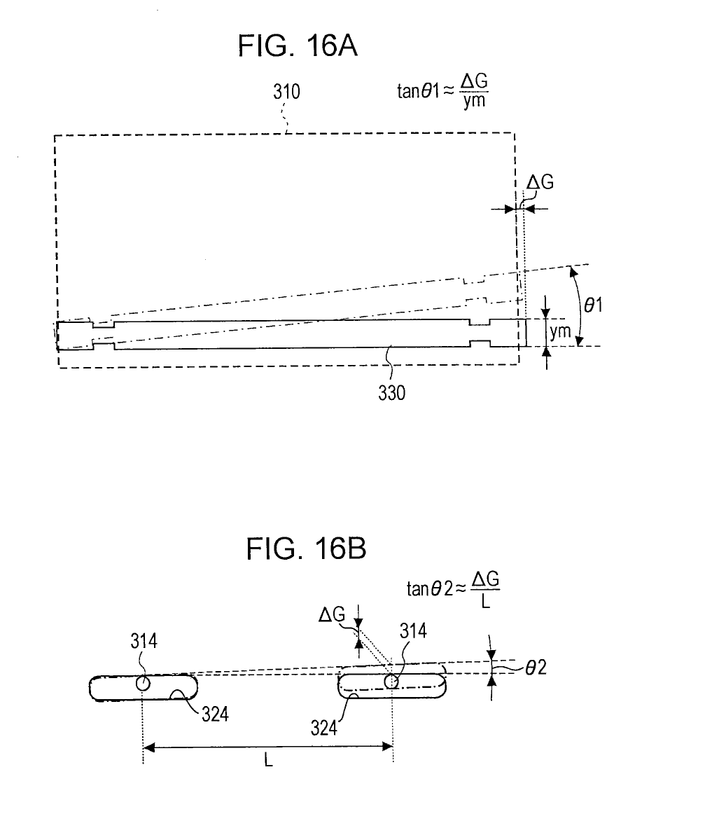

Here, the magnitude of rotational backlash will be described through comparison between a case where no intermediate plate 320 is used and a case where the intermediate plate 320 is used with reference to FIGS. 16(a) and 16(b). FIG. 16(a) represents, with exaggeration, the maximum amount of rotation θ1 in the counterclockwise direction due to rotational backlash of the movable plate 330 with respect to the support plate 310 for the case where no intermediate plate 320 is used. When the dimension of the gap between the movable plate 330 and the support plate 310 is defined as ΔG, and the width of the movable plate is defined as ym, then the relationship between θ1 and ΔG and Ym can be roughly represented by the following formula:

tan θ1≈ΔG/ym (1)

The amount of rotation in the clockwise direction can be considered to be the same, θ1. Meanwhile, FIG. 16(b) shows the relationship between the intermediate plate 320 (the guide grooves 324 therein) and the support plate 310 (the projecting portions 314 thereon) for the case where the intermediate plate 320 is used. When the dimension of the gap between the movable plate 320 and the support plate 310 is defined as AG, and the interval between the two projecting portions 314 is defined as L, then the maximum amount of rotation in the counterclockwise direction due to rotational backlash can be roughly represented by the following formula:

tan θ2≈ΔG/L (2)

While it is necessary to reduce the value of the width ym of the movable plate in the formula (I) as described in the Background Art section, the interval L between the projecting portions 314 can be relatively increased. That is, a dimensional relationship of L>>ym is established. This means θ1>>θ2. In the case where the intermediate plate 320 is used, the relationship between the intermediate plate 320 and the movable plate 330 is also considered in addition to the relationship between the intermediate plate 320 and the support plate 310. Rotational backlash between the intermediate plate 320 and the movable plate 330 is determined by the relationship between the cam grooves 325 of the intermediate plate 320 and the projecting portions 335 of the movable plate 330. In this case, the interval between the projecting portions 335 can be sufficiently increased with respect to the gap between the intermediate plate 320 and the movable plate 330, which results in sufficiently small rotational backlash. Thus, even with such additional rotational backlash taken into consideration, total rotational backlash can be sufficiently reduced compared to the case where no intermediate plate 320 is provided.

Next, a second embodiment will be described.

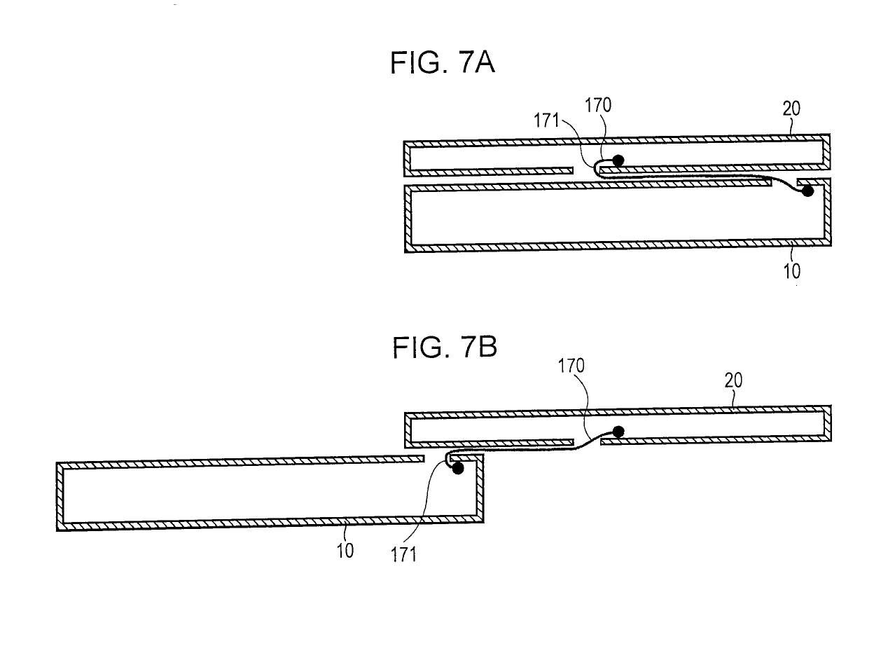

First, an issue to be addressed by the second embodiment will be described with reference to FIG. 7. FIG. 7(a) is a schematic side view of the portable terminal in the closed state. FIG. 7(b) is a schematic side view of the portable terminal in the open state. In the drawing, the slide hinge is not shown for convenience.

In general, electrical connection between the lower housing and the upper housing of the slide-type portable terminal is performed via a flexible cable 170 which is a flexible printed circuit (FPC). For example, in the closed state shown in FIG. 7(a), the flexible cable 170 led out of the first housing 10 serving as the lower housing from the upper end (right end in the drawing) of the housing extends in the direction of the lower end (leftward in the drawing) between the two housings, and is folded back around the middle point to extend to a connection portion in the second housing 20 serving as the upper housing.

In the open state shown in FIG. 7(b), the flexible cable 170 is moved upward (rightward in the drawing) along with a slide operation of the second housing 20. This also moves a folded portion 171 of the flexible cable 170 from around the middle portion of the first housing 10 to the upper end. From what has been discussed above, as the amount of overlap between the upper and lower housings in the open state becomes smaller, the moving distance of the folded portion 171 becomes longer. Therefore, the flexible cable 170 may be exposed to the outside behind the second housing 20 in the open state. Thus, it is conceivable to provide a notched portion in the back surface cover of the slide hinge 30, accommodate the flexible cable 170 in the notched portion, and cover the notched portion with a shutter member.

Patent Document 1 discussed above discloses a technique according to the related art for providing a door portion (shutter mechanism) that opens and closes a hole, which is provided in a slide hinge on the back surface side of an upper housing in the open state and through which a flexible cable 170 passes, in conjunction with operations to open and close a portable terminal. Such a mechanism according to the related art requires a complicated structure.

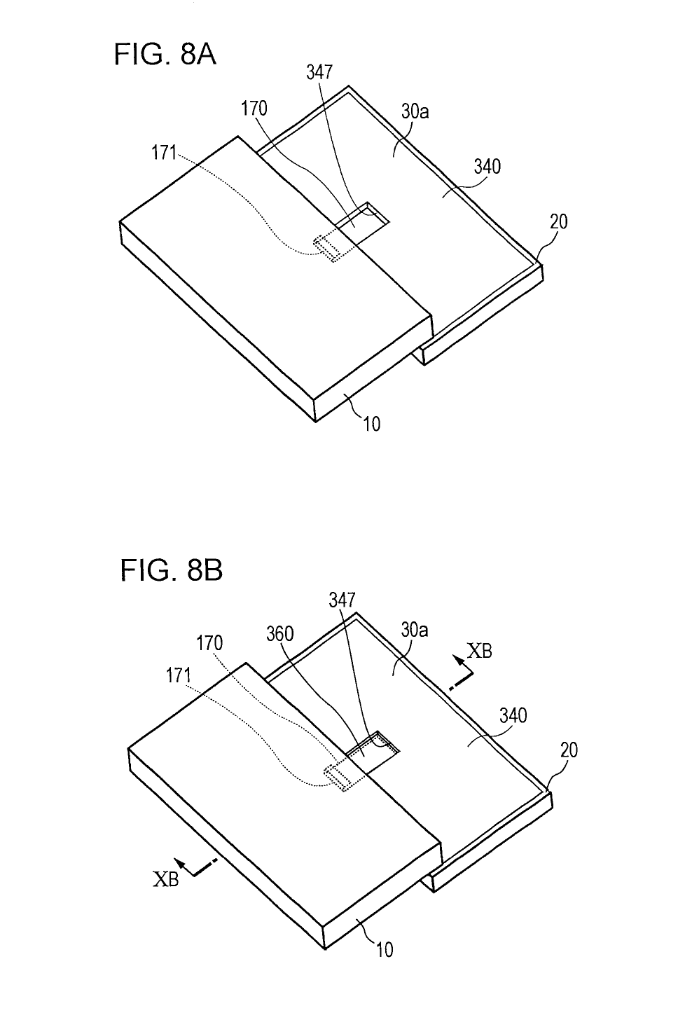

The second embodiment is intended to conveniently achieve a shutter mechanism that opens and closes a shutter member using an intermediate plate in the slide hinge described in relation to the first embodiment in which the intermediate plate is used. FIG. 8(a) shows the portable terminal in the open state, showing a state in which the flexible cable 170 is seen from a notched portion 347 of a slide hinge 30a provided in the back surface of the second housing 20. FIG. 8(b) shows a state in which a window formed by the notched portion 347 is blocked by a shutter member 360.

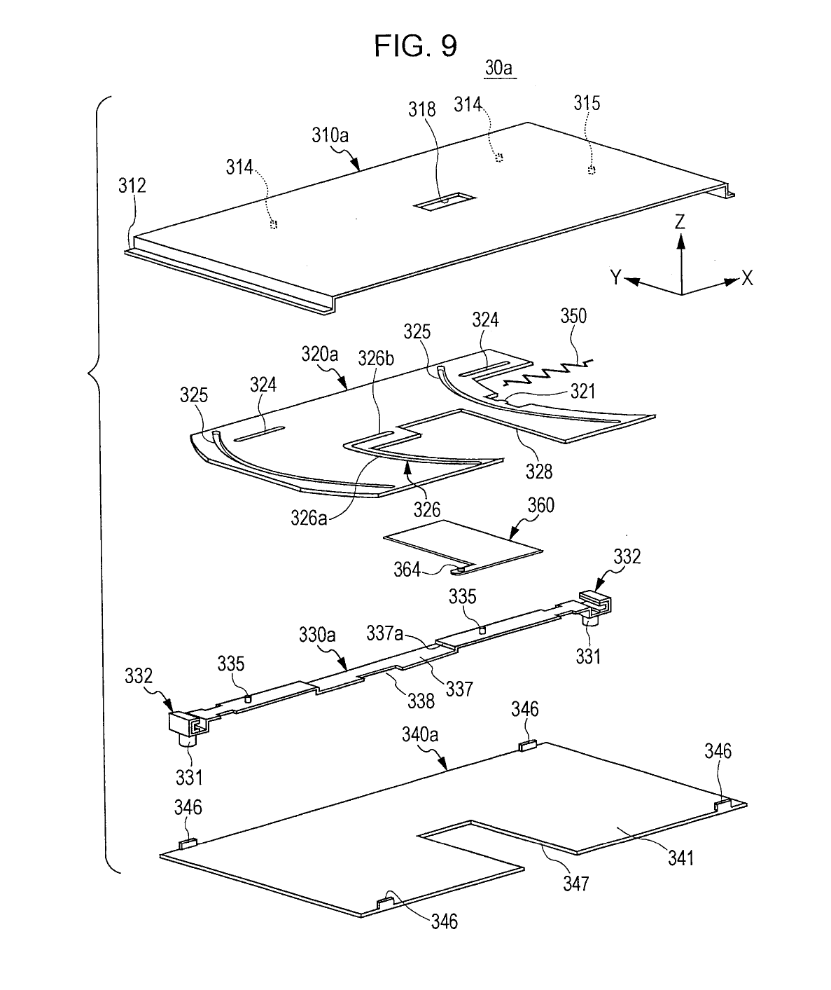

FIG. 9 is an exploded perspective view showing a specific example of the structure of the slide hinge 30a according to the second embodiment. Elements similar to those according to the first embodiment shown in FIG. 3 are denoted by the same reference numerals to omit overlapping description.

An intermediate plate 320a according to the second embodiment is provided with a shutter-driving cam groove 326. The cam groove 326 includes an arcuate section 326a and a straight section 326b that is continuous with one end of the arcuate section 326a. The arcuate section 326a is disposed to extend over substantially half the length of the cam groove 326. The straight section 326b extends straight in the positive X-axis direction from an end portion of the arcuate section 326a on the housing center side. The notched portion 347, which is substantially rectangular, is provided in a back surface cover 340a so that movement of the folded portion of the flexible cable 170 will not be hindered. A support plate 310a is provided with an opening 318 that allows passage of the flexible cable 170.

Further, a shutter member 360 is provided to open and close the notched portion 347 in conjunction with movement of a movable plate 330a in the Y-axis direction (and movement of the intermediate plate 320a in the X-axis direction). A projecting portion (here, pin) 364 projecting upright toward the intermediate plate 320a is provided at a portion of the shutter member 360 on the side of one end (here, on the negative Y-axis direction side) that protrudes in a lateral direction (in the negative X-axis direction). The projecting portion 364 slidably engages with the cam groove 326 to form a cam mechanism (second cam mechanism) together with the cam groove 326. The cam mechanism functions to slide the shutter member 360 (follower) in the Y-axis direction along the cam groove 236 in accordance with a slide operation (reciprocal motion) of the intermediate plate 320a (driver) in the X-axis direction.

The movable plate 330a is formed with a recessed portion 337 in an area overlapping the shutter member 360. The width of the recessed portion 337 in the X-axis direction substantially corresponds to the width of the shutter member 360 in the X-axis direction (including the protruding portion for the projecting portion 364). An upright wall portion 337a on the side of one end of the recessed portion 337 abuts on one side of the shutter member 360, and functions to guide movement of the shutter member 360 in the Y-axis direction. In place of or in addition to the wall portion 337a, the back surface cover 340a may be provided with a guide portion that abuts on at least one side portion of the shutter member 360 to guide movement of the shutter member 360, although not specifically shown. Such a guide portion may be provided by deforming the back surface cover 340a itself, or by adding a separate member (not shown) to a surface of the back surface cover 340.

In addition, although not an essential element, a notched portion 338 having a length substantially corresponding to the width of the flexible cable 170 is provided in a side portion of the recessed portion 337 of the movable plate 330a in the negative Y-axis direction. The width of the notched portion 338 is large enough to accommodate the width of the flexible cable 170. The depth of the notched portion 338 is large enough to accommodate the thickness of the flexible cable 170.

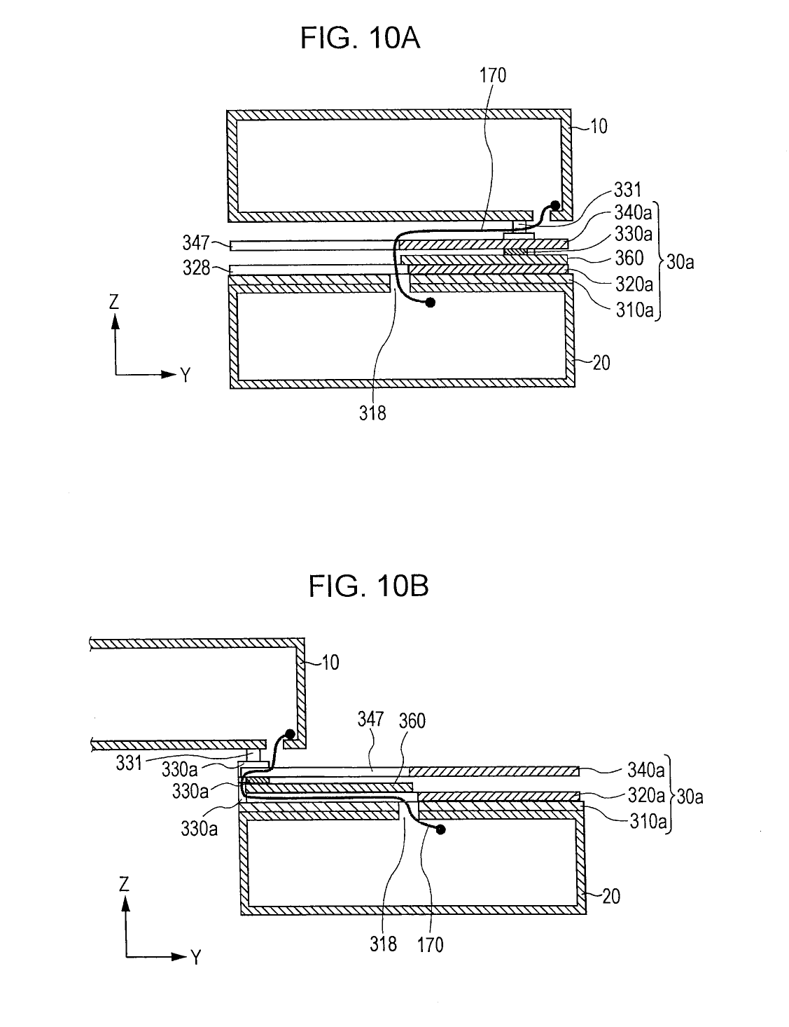

FIG. 10 is a schematic diagram showing how the flexible cable 170 coupling between the first housing 10 and the second housing 20 passes through the slide hinge 30a according to the embodiment in the portable terminal according to the embodiment. FIG. 10(a) is a cross-sectional view of the portable terminal in the closed state. FIG. 10(b) is a cross-sectional view of the portable terminal in the open state. FIG. 10(b) corresponds to a cross-sectional view of the portable terminal of FIG. 8(b) taken along the line I-I. The cross-sectional views are side cross-sectional views showing a cross section taken along the center line of the shutter member 360 in the longitudinal direction as seen from the side on which the spring 350 is not provided. In FIG. 10, the dimensions such as thickness and length of each element may be varied from the actual dimensions for viewability of the drawing.

In the closed state shown in FIG. 10(a), the flexible cable 170, one end of which is connected to a printed circuit in the first housing 10 or the like, is led out of the first housing 10 from the upper end (right end in the drawing) of the housing in the drawing. The flexible cable 170 further extends inward (leftward in the drawing) through a gap between the outer wall of the first housing 10 and the back surface cover 340a of the slide hinge 30a. The flexible cable 170 further passes through the notched portion 347 of the back surface cover 340a, the notched portion 328 of the intermediate plate 320a, and the opening 318 of the support plate 310a so that the other end of the flexible cable 170 is connected to a printed circuit in the second housing 20 or the like. In the closed state, the shutter member 360 is retracted from the notched portion 328 to an unnotched area of the back surface cover 340a. This allows the flexible cable 170 to be folded back at the middle portion of the back surface cover 340a.

In the open state shown in FIG. 10(b), the first housing 10 has been moved to the lower end (left end in the drawing) of the second housing 20 together with the movable plate 330a. In this state, the flexible cable 170 led out of the first housing 10 passes through the vicinity of the outer side (negative Y-axis direction side) of the notched portion 347 of the back surface cover 340a and a side portion of the intermediate plate 320a (notched portion 328) to be led into the second housing 20 through the opening 318 of the support plate 310a. In the open state, the shutter member 360 is advanced to cover the flexible cable 170 extending in the notched portion 328 of the intermediate plate 320a.

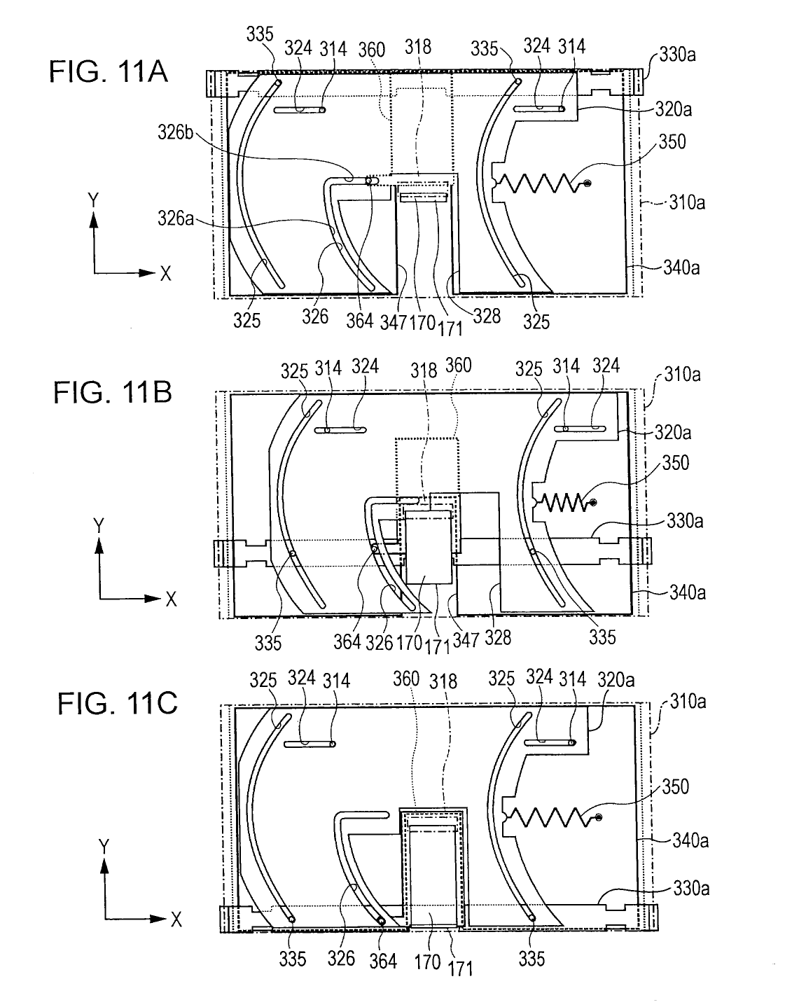

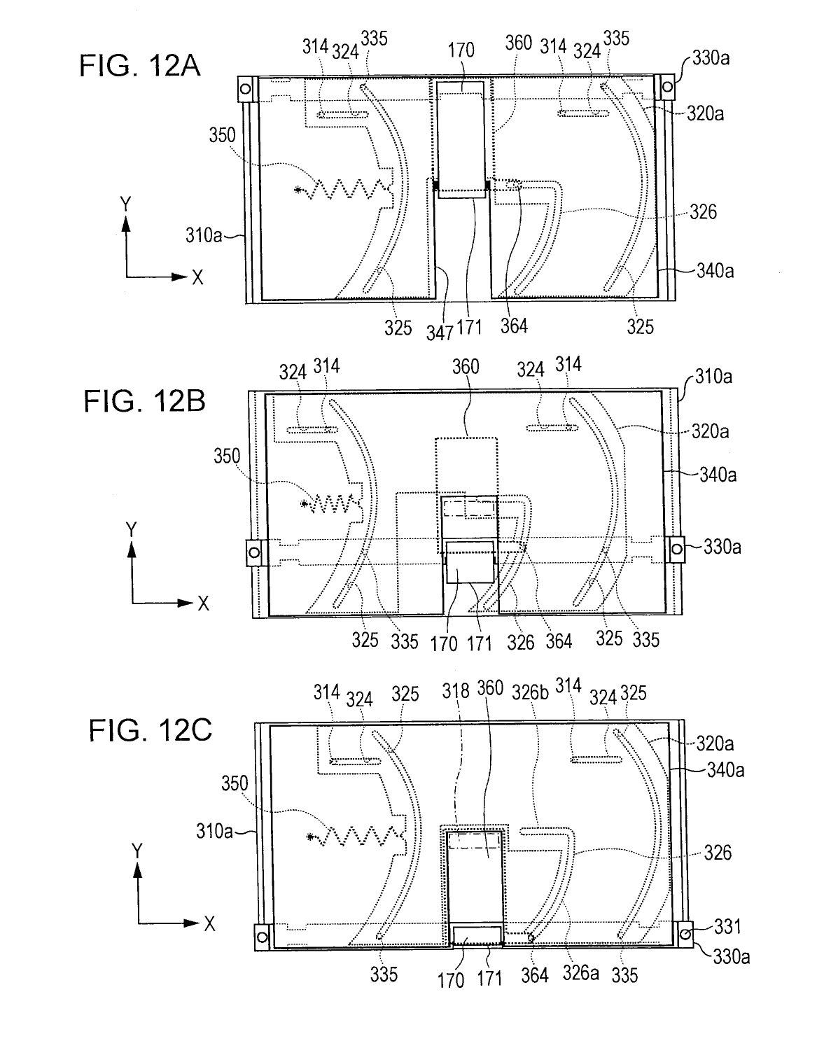

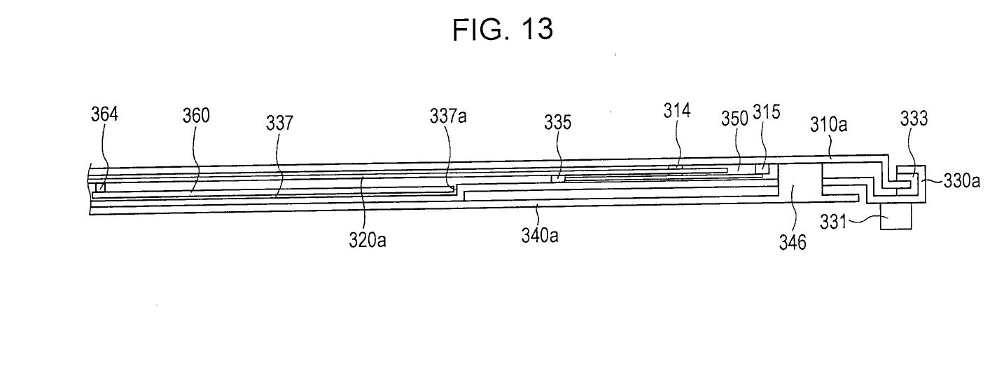

An operation of the slide hinge 30a according to the second embodiment will be described with reference to FIGS. 11, 12, and 13. FIGS. 11(a) to 11(c) show the slide hinge 30a as seen from its upper surface with the portable terminal in the closed state, the intermediate state, and the open state, respectively. In FIG. 11, the uppermost support plate 310a is indicated by the phantom line. FIGS. 12(a) to 12(c) show the slide hinge 30a as seen from its back surface with the portable terminal in the closed state, the intermediate state, and the open state, respectively. FIG. 13 is a side view of a main portion of the slide hinge 30a in the state of FIG. 11(b) as seen from the front side.

A basic operation of the slide hinge 30a regarding the support plate 310a and the movable plate 330a is the same as the operation of the slide hinge 30 according to the first embodiment discussed above, and thus overlapping description is omitted.

In the closed state shown in FIGS. 11(a) and 12(a), the shutter member 360 is in the fully open state. At this time, the projecting portion 364 of the shutter member 360 is positioned in the straight section 326b of the cam groove 326, and the main portion of the shutter member 360 is hidden behind the back surface cover 340a. The movable plate 330a is positioned at the upper end portion of the support plate 310a (upper end in the positive Y-axis direction). The upper end portion of the flexible cable 170 on the first housing 10 side (upper end in the positive Y-axis direction) is positioned substantially at the same position as the movable plate 330a. The folded portion 171 of the flexible cable 170 is located in the vicinity of the center of the second housing 20.

When the movable plate 330a starts moving with respect to the support plate 310a in the negative Y-axis direction (downward in the drawing) to bring the portable terminal from the closed state into the open state, the shutter member 360 is maintained in the fully open state until the vicinity of the dead point is reached. During a period from the closed state until the dead point is reached, the projecting portion 364 of the shutter member 360 moves along the horizontal straight section 326b of the cam groove 326.

Thereafter, as shown in FIGS. 11(b) and 12(b), as the movable plate 330a moves from around the dead point to bring the portable terminal into the open state, the folded portion of the flexible cable 170 moves toward the open end of the notched portion 347. The area of a portion of the shutter member 360 that covers the notched portion 347 gradually increases as if to follow the folded portion.

In the open state shown in FIGS. 11(c) and 12(c), the shutter member 360 has been moved to a position at which it completely covers the notched portion 347. During a period from the dead point until the open state is reached, the projecting portion 364 moves along the arcuate section 326a of the cam groove 326. That is, movement of the movable plate 330a with respect to the support plate 310a moves the intermediate plate 320a in the positive X-axis direction (rightward in the drawing). Along with such movement, further, the shutter member 360 is moved in the negative Y-axis direction (downward in the drawing) by the action of the cam groove 326.

Such an operation allows the notched portion 347 of the back surface cover 340a to be covered by the shutter member 360 even if the notched portion 347 is exposed to the outside behind the second housing 20. As a result, the flexible cable 170 can be prevented from being exposed to be seen.

According to the embodiment, the cam mechanism provided in the shutter member 360 and the intermediate plate 320a achieves a shutter mechanism with an extremely simple configuration. In particular, providing the cam groove 326 with the arcuate section 326a and the straight section 326b which is continuous with the arcuate section 326a achieves, with a high degree of freedom, correlation between moving operations of the shutter member and the intermediate plate 320a in which movement of the shutter member is stopped with the intermediate plate 320a in a part of its moving range. In addition, extra parts such as a spring for the shutter mechanism are not needed. Moreover, an increase in thickness of the portable terminal due to the addition of the shutter mechanism can be minimized.

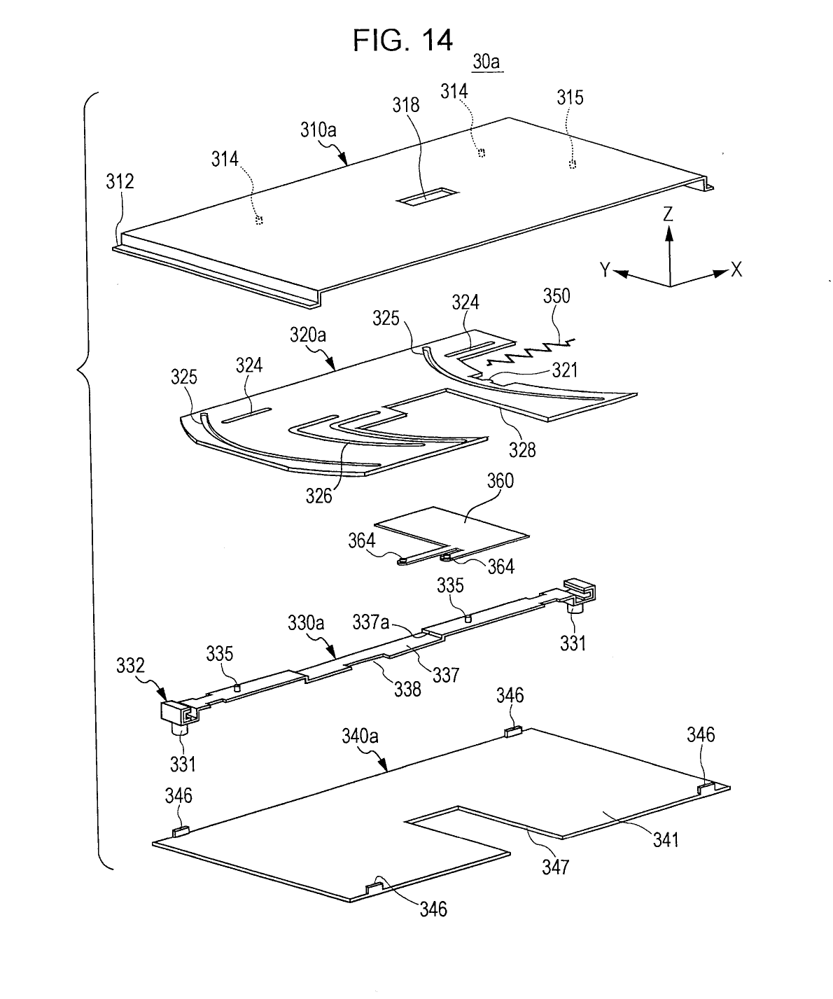

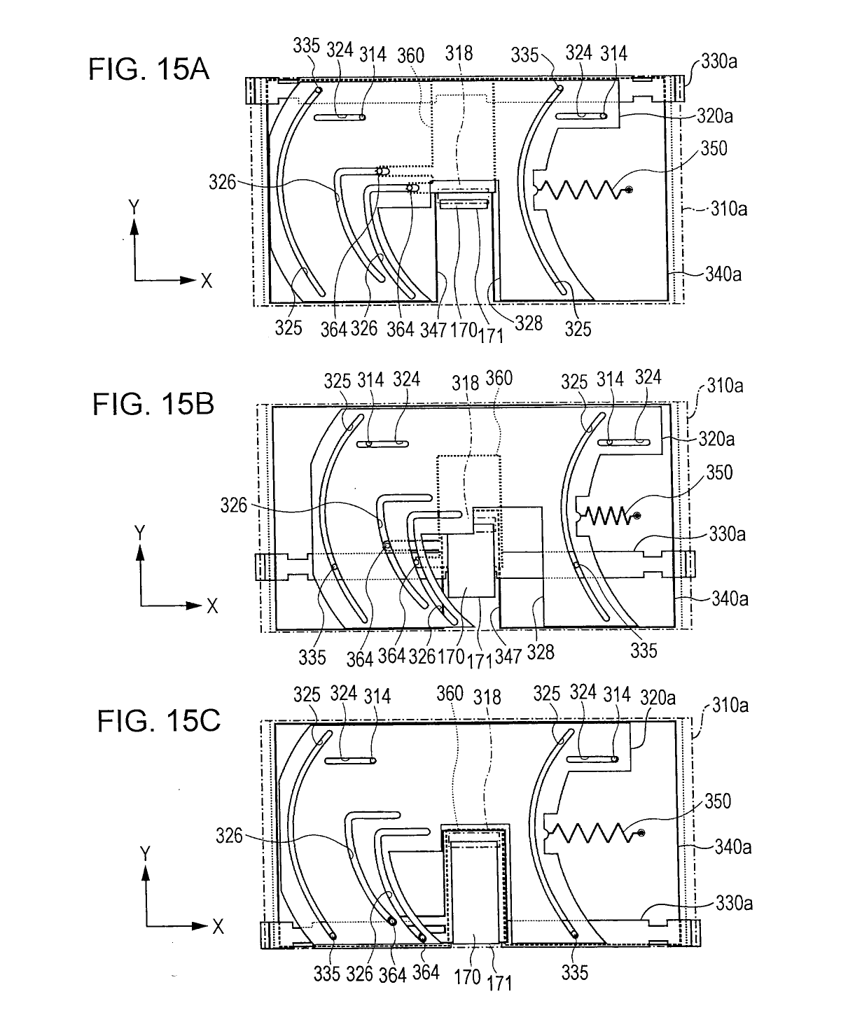

As a modification of the second embodiment, a plurality of sets of shutter-driving cam grooves 326 and projecting portions 364 may be provided for the shutter mechanism. FIGS. 14 and 15 show an example in which two sets of cam grooves 326 and projecting portions 364 are provided on one side of the shutter member 360. Although not shown, first and second sets of cam grooves 326 and projecting portions 364 may be provided separately on both sides of the shutter member if the arrangement space permits.

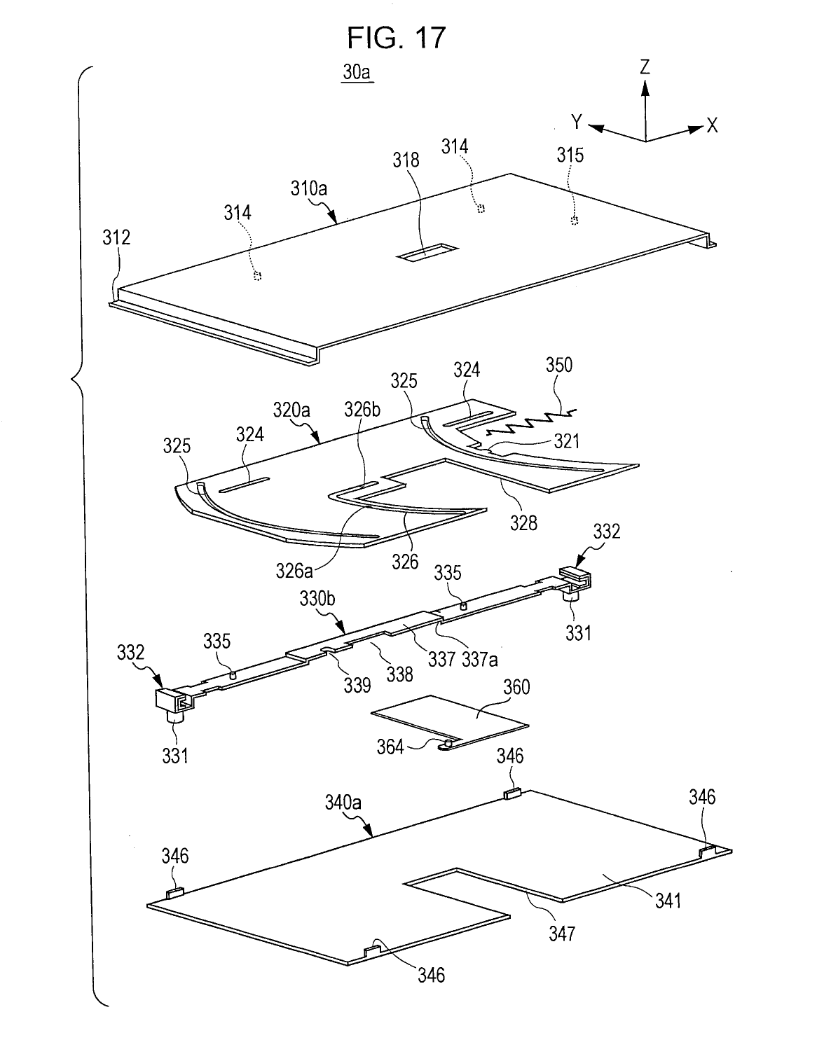

FIG. 17 is an exploded perspective view of a slide hinge according to another modification of the second embodiment. Elements that are the same as the elements shown in FIG. 9 are denoted by the same reference numerals to omit overlapping description. In the configuration shown in FIG. 17, the arrangement of a shutter member and a movable plate is inverted from that in the configuration of FIG. 9. That is, in FIG. 9, the shutter member 360 is disposed between the movable plate 330a and the intermediate plate 320a. In FIG. 17, in contrast, the shutter member 360 is disposed between a movable plate 330b and the back surface cover 340a. In the example, a notched portion 339 is formed in the movable plate 330b at a position on which the projecting portion 364 of the shutter member 360 abuts so as not to hinder the projecting portion 364 from engaging with the cam groove 325 of the intermediate plate 320a. Along with the change to the position at which the shutter member 360 is disposed, in addition, the recessed portion 337 formed in the movable plate 330b is provided in the surface opposite to that in FIG. 9 (on the intermediate plate 320a side).

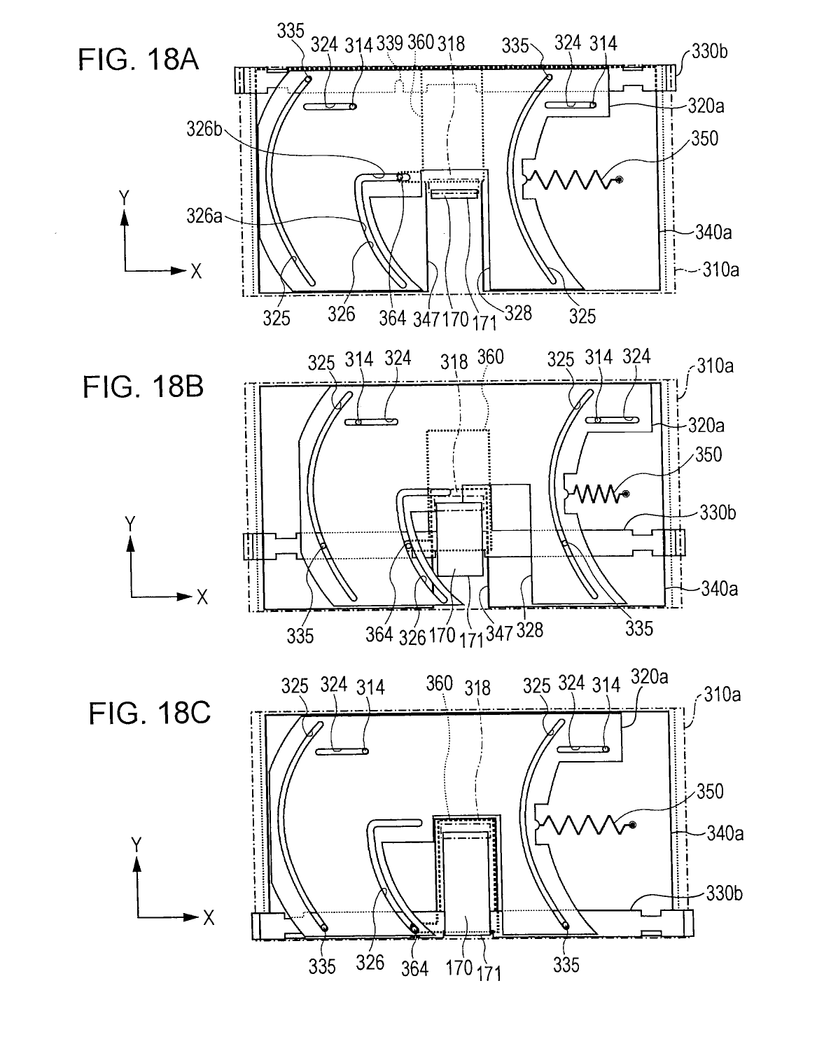

An operation of the slide hinge according to the modification of FIG. 17 will be described with reference to FIGS. 18(a) to 18(c). A basic operation is the same as described with reference to FIG. 11. A difference lies in that the projecting portion 364 of the shutter member 360 is positioned in the notched portion 339 during a period from the intermediate state of FIG. 18(b) until the closed state of FIG. 18(c) is reached. The advantage of this configuration is as follows. During a period from the closed state of FIG. 18(a) until the intermediate state of FIG. 18(b) is reached, the projecting portion 364 of the shutter member 360 moves from the terminal position in the straight section 326b to reach the boundary between the straight section 326b and the arcuate section 326a along with a slide operation of the movable plate 330b and the intermediate plate 320a. The intermediate plate 320a reaches the right end of its moving range in the positive X-axis direction. During this period, the projecting portion 364 of the shutter member 360 is disengaged from the notched portion 339 of the movable plate 330b. Thereafter, as the movable plate 330b continuously moves toward its position in the open state of FIG. 18(c), the intermediate plate 320a starts returning in the negative X-axis direction. At this time, the movable plate 330b abuts on the projecting portion 364 of the shutter member 360 to push the projecting portion 364 in the negative Y-axis direction, which assists the projecting portion 364 in advancing to the arcuate section 326a side rather than returning to the straight section 326b side.

A plurality of cam grooves 326 discussed above may also be provided in the modification shown in FIG. 17.

The embodiment discussed above provides a portable terminal including:

a first housing;

a second housing; and

a slide hinge that couples the second housing to the first housing so as to be slidable with respect to the first housing in a first direction between a closed state and an open state,

in which the slide hinge includes
a support plate fixed to the second housing,
a movable plate coupled to the first housing and supported so as to be slidable with respect to the support plate along the first direction, and
an intermediate plate that cooperates with the support plate and the movable plate,

the intermediate plate is supported by the support plate so as to be slidable with respect to the support plate in a second direction, and

the intermediate plate and the movable plate include a cam mechanism that slides the intermediate plate in the second direction in accordance with a slide operation of the movable plate along the first direction.

The embodiment also provides the portable terminal, further including an elastic member that exerts an urging force in the direction of moving the intermediate plate away from or closer to the support plate along the second direction such that the portable terminal is brought into first and second stable states with the movable plate at one end and the other end, respectively, of a moving range in the first direction.

The embodiment also provides the portable terminal, in which the cam mechanism is formed by first and second cam grooves provided in the intermediate plate, and first and second projecting portions provided on the movable plate to engage with the first and second cam grooves, respectively.

The embodiment also provides the portable terminal, in which the guide mechanism is formed by first and second guide grooves provided in one of the intermediate plate and the support plate, and first and second projecting portions provided on the other of the intermediate plate and the support plate to engage with the guide grooves, respectively.

The slide hinge includes a notched portion provided in a back surface to allow passage of a flexible cable for electrical connection between the first housing and the second housing.

The embodiment also provides the portable terminal, in which the slide hinge further includes a shutter member that blocks a portion of the notched portion that is exposed in the open state, the shutter member and the intermediate plate include a second cam mechanism, and the second cam mechanism causes the shutter member to open and close the notched portion in conjunction with movement of the intermediate plate.

The embodiment also provides the portable terminal, in which the second cam mechanism is formed by a shutter-driving cam groove provided in the intermediate plate and a projecting portion provided on the shutter member, and the shutter member is slid in the first direction in accordance with a slide operation of the intermediate plate in the second direction.

The embodiment additionally provides a slide hinge that couples a second housing to a first housing so as to be slidable with respect to the first housing in a first direction between a closed state and an open state, including:

a support plate fixed to the second housing;

a movable plate coupled to the first housing and supported so as to be slidable with respect to the support plate along the first direction; and

an intermediate plate that cooperates with the support plate and the movable plate,

in which the intermediate plate is supported by the support plate so as to be slidable with respect to the support plate in a second direction, and

the intermediate plate and the movable plate include a cam mechanism that slides the intermediate plate in the second direction in accordance with a slide operation of the movable plate along the first direction.

While preferred embodiments have been described above, various changes and modifications other than those mentioned above may be made. That is, it should be understood as a matter of course by those skilled in the art that various modifications, combinations, and other embodiments may occur depending on design requirements and other factors insofar as they are within the scope of the appended claims or the equivalents thereof.

For example, while the cam mechanism is formed by a combination of projecting portions (pins) and grooves, the claimed invention is not limited to such a combination. Any mechanism that can convert slide movement of a member in one direction into slide movement of another member in another direction may be used.

Similarly, the guide mechanism is formed by a combination of projecting portions (pins) and grooves. However, the claimed invention is not limited to such a combination, and any mechanism that can guide movement of the intermediate plate 320, 320a in one direction may be used.

The back surface cover 340, 340a is not an essential element of the slide hinge 30, 30a.

The curved shape of the cam groove 325 is not limited to an arcuate shape, and may be any shape that brings the slide hinge into a stable state with the movable plate 330 at both ends of its movable range with respect to the support plate 310, and that brings the slide hinge into an unstable state with the movable plate 330 at the middle of the movable range. For example, the cam groove 325 may have the shape of a letter “<” obtained by folding a straight line.

The relationship between the projecting portions (pins) and the grooves may be inverted. For example, while the projecting portions 314 are provided on the support plate 310 and the guide grooves 324 are provided in the intermediate plate 320, the guide grooves may be provided in the support plate 310 and the projecting portions may be provided on the intermediate plate 320.

While the slide direction of the housings is set to the direction parallel with the short sides of the housings, the slide direction may be set to the direction parallel with the long sides of the housings.

### REFERENCE SIGNS LIST

10: first housing (lower housing)
20: second housing (upper housing)
30: slide hinge
30a: slide hinge
170: flexible cable
310: support plate
310a: support plate
312: guide rail portion
314: projecting portion
315: support plate
315: fastening portion
316: flat plate member
318: opening
320: intermediate plate
320a: intermediate plate
321: fastening portion
324: guide groove
325: cam groove
326: cam groove
326a: arcuate section
326b: straight section
328: notched portion
330: movable plate
330a: movable plate
330b: movable plate
331: attachment portion
332: slide engagement portion
335: projecting portion
336: plate-like member
337: recessed portion
337a: wall portion
338: notched portion
339: notched portion
340: back surface cover
340a: back surface cover
341: flat plate member
346: lug
347: notched portion
350: spring
360: shutter member
364: projecting portion
366: projecting portion

What is claimed is:

1. A terminal apparatus comprising:
a first housing;
a second housing; and
a slide hinge that couples the second housing to the first housing such that the second housing is slidable with respect to the first housing in a first direction between a closed state and an open state,
wherein the slide hinge includes
a support plate fixed to the second housing,
a movable plate slidably coupled to the first housing with respect to the support plate along the first direction,
an intermediate plate slidably supported by the support plate with respect to the support plate in the second direction, and
a cam mechanism that slides the intermediate plate in the second direction in accordance with a slide operation of the movable plate along the first direction.

2. The terminal apparatus according to claim 1, wherein the slide hinge further includes an elastic member configured to exert an urging force to the intermediate plate along the second direction to move the intermediate plate away from or closer to the support plate.

3. The terminal apparatus according to claim 2, wherein the intermediate plate includes at least one cam groove that has a portion extending in a direction that is between the first direction and the second direction, and the support plate includes at least one projecting portion that slidably engages with the at least one cam groove.

4. The terminal apparatus according to claim 3, wherein the urging force provided by the elastic member is based on a movement of the at least one projecting portion within the at least one cam groove.

5. The terminal apparatus according to claim 3, wherein the at least one cam groove has an arc shape.

6. The terminal apparatus according to claim 2, wherein the elastic member exerts the urging force to the intermediate plate such that the terminal apparatus is brought into first and second stable states with the movable plate at one end of a moving range in the first direction in the first stable state and at the other end of the moving range in the first direction in the second stable state.

7. The terminal apparatus according to claim 1, wherein the intermediate plate includes at least one groove extending in the second direction, and the support plate includes at least one projecting portion that slidably engages with the at least one groove.

8. The terminal apparatus according to claim 1, wherein a back surface of the slide hinge further includes a notched portion configured to allow passage of a flexible cable for an electrical connection between the first housing and the second housing.

9. The terminal apparatus according to claim 8, wherein the slide hinge further includes a shutter member configured to open and close the notched portion in conjunction with movement of the intermediate plate such that the shutter member blocks a portion of the notched portion that is exposed when the terminal apparatus is in the open state.

10. The terminal apparatus according to claim 9, wherein the intermediate plate further includes a shutter-driving cam groove and the shutter member includes a projecting portion that engages the shutter-driving cam groove, and the shutter member is configured to slide in the first direction in accordance with a slide operation of the intermediate plate in the second direction.

11. A slide hinge that couples a second housing of a terminal apparatus to a first housing of the terminal apparatus such that the second housing is slidable with respect to the first housing in a first direction between a closed state and an open state, the slide hinge comprising:
a support plate fixed to the second housing,
a movable plate slidably coupled to the first housing with respect to the support plate along the first direction,
an intermediate plate slidably supported by the support plate with respect to the support plate in the second direction, and
a cam mechanism that slides the intermediate plate in the second direction in accordance with a slide operation of the movable plate along the first direction.
